(19) United States
(12) Patent Application Publication
(10) Pub. No.: US 2022/0100624 A1
(43) Pub. Date: Mar. 31, 2022

(54) METHOD AND SYSTEM OF IDENTIFYING AND ESTIMATING COMPLEX ANALOG CIRCUIT FAILURE

(71) Applicant: WUHAN UNIVERSITY, Hubei (CN)

(72) Inventors: Yigang HE, Hubei (CN); Ming Xiang, HUBEI (CN); Hui ZHANG, Hubei (CN); Zhaorong Zeng, HUBEI (CN); Zhijian Hu, HUBEI (CN); Fuping Zeng, HUBEI (CN); Kaipei LIU, HUBEI (CN)

(73) Assignee: WUHAN UNIVERSITY, HUBEI (CN)

(21) Appl. No.: 17/168,144

(22) Filed: Feb. 4, 2021

(30) Foreign Application Priority Data
Sep. 25, 2020 (CN) 202011021794.1

(51) Int. Cl. G06F 11/22; G06F 11/26; G06N 3/04; G06N 3/08

(52) U.S. Cl. CPC G06F 11/2263; G06N 3/08; G06N 3/0454; G06F 11/261

(57) ABSTRACT

A method and a system of identifying and estimating a complex analog circuit failure, belonging to the field of power electronic circuit failure prediction. The method includes the following steps: building a degradation simulation model of an analog circuit to be diagnosed, performing a parameter aging simulation experiment on different devices; extracting a time domain feature of each of output signals by using a time-series transformation method, building a health index of each of the devices based on angle similarity; identifying whether the analog circuit to be diagnosed is degraded and a starting point of degradation by combining a time moving window and a convolutional neural network; multiplexing part of hidden layers of the convolutional neural network and a long short term memory-recurrent neural network to estimate a health state of a degraded analog circuit; and evaluating prediction accuracy.

### CROSS-REFERENCE TO RELATED APPLICATION

This application claims the priority benefit of China application serial no. 202011021794.1, filed on Sep. 25, 2020. The entirety of the above-mentioned patent application is hereby incorporated by reference herein and made a part of this specification.

### BACKGROUND

### Technical Field

The disclosure relates to a field of power electronic circuit failure prediction, and in particular, to a method and a system of identifying and estimating a complex analog circuit failure.

### Description of Related Art

With the development of the ubiquitous electric Internet of Things, automobiles, aircraft, and power systems are considerably integrated, and complexity of interaction among internal components in a system increases. Consequently, cleaning and stable operating of power equipment becomes more and more difficult. Therefore, the demand for degradation of analog circuits has attracted attention.

Degradation may occur at all stages of operation of an analog circuit. Measures may be taken in time to identify early circuit degradation to avoid further economic and property losses. At the same time, the original equipment may be preserved to the greatest extent to ensure the normal operation of experiments and production.

To be specific, in an analog circuit, various devices, namely a capacitor, a resistor, an inductor, a power switch, etc., may experience degradation of performance and parameters. Due to the different roles of various devices in an analog circuit, various degradations have different effects on equipment operation. If the degradation state and degree of the circuit may be evaluated in time, the production unit may take measures in time, such as component and device replacement, spare equipment activation, production plan increasing or decreasing, etc.

The system health prediction methods may generally be divided into three categories: the model-based method, the data-based method, and the hybrid prediction method. The model-based method uses mathematical models or physical models to model a predictive model. Since this model has extremely high requirements for parameter settings, temperatures or the external load capacity may affect the accuracy of the parameters. Prediction accuracy of the model may thereby be affected. In addition, the original signal affected by noise may also affect the accuracy of the parameters. Therefore, the model-based method has extremely high requirements for the accuracy of system parameters. Accordingly, the modeling process of this method is complicated, and the calculation cycle is long and complicated. The data-based prediction method only considers the input and output amounts of the system, and regression or classification is performed through informatics theory. This method thus exhibits high computational efficiency and strong anti-interference ability. The hybrid prediction method combines the advantages of the two types of methods. Nevertheless, the hybrid prediction method relies on the model-based prediction method, so the internal calculation complexity is still high, the comprehensive modeling costs are high, and parameter dependence is strong.

### SUMMARY

In view of the above defects or improvement requirements of the related art, the disclosure provides a method and a system of identifying and estimating a complex analog circuit failure capable of stably and effectively identifying circuit degradation for early degradation identification and degradation estimation of an analog circuit and ensuring accurate degradation estimation.

To realize the above purpose, according to one aspect of the disclosure, a method of identifying and estimating a complex analog circuit failure is provided, and the method includes the following steps.

(1) A degradation simulation model of an analog circuit to be diagnosed is built, a parameter aging simulation experiment is performed on different devices, and output signals of the devices under various parameter conditions are collected.
(2) A time domain feature of each of the output signals is extracted by using a time-series transformation method, and a health index of each of the devices is built according to the time domain feature.
(3) Whether the analog circuit to be diagnosed is degraded is identified based on the health index of each of the devices combined with a time moving window and a convolutional neural network (CNN).
(4) Part of hidden layers of the convolutional neural network are multiplexed together with a long short term memory-recurrent neural network (LSTM-RNN) to estimate a state of a degraded circuit.

In an embodiment of the disclosure, the health index of each of the devices is built through

$$d i s ( {x}_{1} , {x}_{2} ) = 1 - {cos}^{- 1} ( \frac{{x}_{1} \cdot {x}_{2}}{\vert {x}_{1} \vert \vert {x}_{2} \vert} ) \cdot \frac{1}{π} ,$$

where x₁=(x₁⁽¹⁾, x₁⁽²⁾, . . . , x₁⁽ⁿ⁾) refers to the time domain feature of the output signal of the device under a healthy state, x₂=(x₂⁽¹⁾, x₂⁽²⁾, . . . , x₂⁽ⁿ⁾) refers to the time domain feature of the output signal of the device in an aging process, and n represents a length of a time domain feature vector.

In an embodiment of the disclosure, in step (2), ten time domain features of the extracted output signals are: tf₁=max(sₜ),

$${tf}_{2} = \frac{1}{N} {\sum }_{t = 1}^{N} {s}_{t} , \\ {tf}_{3} = \frac{1}{N} {\sum }_{t = 1}^{N} {s}_{t}^{2} , \\ {tf}_{4} = \sqrt{\frac{1}{N} {\sum }_{t = 1}^{N} {( {s}_{t} - \overline{s} )}^{2}} , \\ {tf}_{5} = \sqrt{\frac{1}{N} {\sum }_{t = 1}^{N} {( {s}_{t} - \overline{s} )}^{3}} , \\ {tf}_{6} = \frac{{tf}_{5}^{2}}{{tf}_{4}^{3}} , \\ {tf}_{7} = \frac{{tf}_{1}}{\vert \overline{s} \vert} , \\ {tf}_{8} = \frac{{tf}_{1}}{{tf}_{3}} , \\ {tf}_{9} = \frac{{tf}_{1}}{{tf}_{2}} , and$$

$${tf}_{10} = \frac{\frac{1}{N} {\sum }_{t = 1}^{N} {( {s}_{t} - \overline{s} )}^{4}}{{tf}_{4}^{4}} ,$$

where sₜ is an output signal value at a t point in a current secondary degradation process, N is a total number of output signal points of a secondary degradation sample, and s̅ represents an arithmetic average value of the output signals of the secondary degradation sample.

In an embodiment of the disclosure, the convolutional neural network comprises three types of hidden layers comprising a convolutional layer, a pooling layer, and a Softmax layer. The time moving window is realized by truncating a certain number of signal features in a given length of a degradation period, such that the time moving window establishes a signal matrix, Each of the signal features is divided into each row of the signal matrix, and a column number of the signal matrix corresponds to a degradation cycle number of a column signal.

In an embodiment of the disclosure, step (3) further includes the following steps. The signal matrix truncated by the time moving window is identified through the convolutional neural network to identify whether the analog circuit to be diagnosed is degraded. The degradation cycle number at which the degradation starts is further determined if the analog circuit to be diagnosed is degraded.

In an embodiment of the disclosure, step (4) further includes the following steps. Hidden feature information of an input signal of the degraded circuit extracted by the convolutional neural network is sent in the long short term memory-recurrent neural network for health state estimation. An AdaGrad algorithm is adopted to update a network parameter.

In an embodiment of the disclosure, the method further includes the following step. A related evaluation indicator is adopted to evaluate a prediction effect. The evaluation indicator includes: a scoring function and a root mean square error.

According to another aspect of the disclosure, the disclosure provides a system of identifying and estimating a complex analog circuit failure. The system includes a data collection module, a data processing module, an identification module, and a state estimation module. The data collection module is configured to build a degradation simulation model of an analog circuit to be diagnosed, perform a parameter aging simulation experiment on different devices, and collect output signals of the devices under various parameter conditions. The data processing module is configured to extract a time domain feature of each of the output signals by using a time-series transformation method and build a health index of each of the devices according to the time domain feature. The identification module is configured to identify whether the analog circuit to be diagnosed is degraded based on the health index of each of the devices combined with a time moving window and a convolutional neural network (CNN). The state estimation module is configured to multiplex part of hidden layers of the convolutional neural network together with a long short term memory-recurrent neural network (LSTM-RNN) to estimate a state of a degraded circuit.

Preferably, the system further includes an evaluation module, adopting a related evaluation indicator to evaluate a prediction effect. The evaluation indicator includes: a scoring function and a root mean square error.

According to another aspect of the disclosure, the disclosure further provides a computer readable storage medium storing a computer program. The computer program performs any step of the method when being executed by a processor.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic flow chart of a method of identifying circuit degradation and estimating a health state according to an embodiment of the disclosure.

FIG. 2 is a diagram of degradation simulation topology of an analog circuit according to an embodiment of the disclosure.

FIG. 3 is a graph of a discharge voltage waveform according to an embodiment of the disclosure.

FIG. 4 are schematic graphs of health index curves according to an embodiment of the disclosure, where (a) is the L₂₋₁ health index curve, (b) is the L₁₋₁ health index curve, (c) is the C₂₋₁ health index curve, (d) is the C₁₋₁ health index curve, (e) is the L₃₋₁ health index curve, and (f) is the K₁₋₁ health index curve.

FIG. 5 are schematic diagrams of a time moving window and calculation of a convolutional neural network according to an embodiment of the disclosure, where (a) represents the time moving window, and (b) represents calculation steps of the convolutional neural network.

FIG. 6 is schematic diagram of calculation of a single long short term memory (LSTM) unit according to an embodiment of the disclosure.

FIG. 7 is a diagram of a structure of a multiplexing neural network according to an embodiment of the disclosure.

FIG. 8 are graphs of part of health index prediction results according to an embodiment of the disclosure, where (a) is testing sample #4, (b) is testing sample #36, (c) is testing sample #56, (d) is testing sample #66, (e) is testing sample #75, (f) is testing sample #92, (g) is testing sample #103, (h) is testing sample #112, and (i) is testing sample #116.

FIG. 9 is a schematic diagram of a structure of a system according to an embodiment of the disclosure.

### DESCRIPTION OF THE EMBODIMENTS

To better illustrate the goal, technical solutions, and advantages of the disclosure, the following embodiments accompanied with drawings are provided so that the disclosure are further described in detail. It should be understood that the specific embodiments described herein serve to explain the disclosure merely and are not used to limit the disclosure. In addition, the technical features involved in the various embodiments of the disclosure described below can be combined with each other as long as the technical features do not conflict with each other.

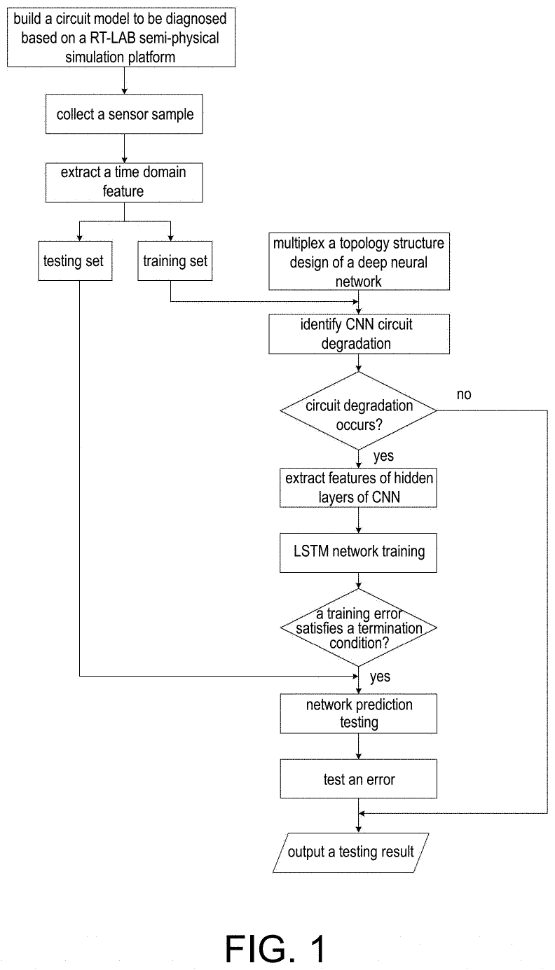

As shown in FIG. 1, a method of identifying and estimating a complex analog circuit failure is provided and includes the following steps.

A degradation simulation model of an analog circuit to be diagnosed is built, and a parameter aging simulation experiment is performed on different devices. Currents or voltages of a plurality of branches are selected as an observation monitoring circuit, and output signals of the devices under various parameter conditions are collected.

In the embodiments of the disclosure, the parameter aging simulation experiment on different devices may be performed based on an energy assembly module circuit of large-scale laser convergence equipment of the China Academy of Engineering Physics, and specific steps are provided as follows.

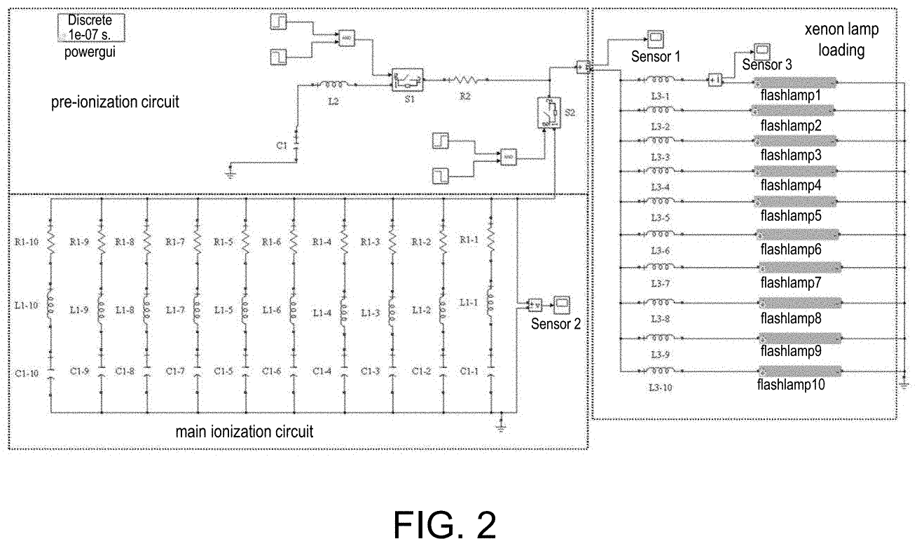

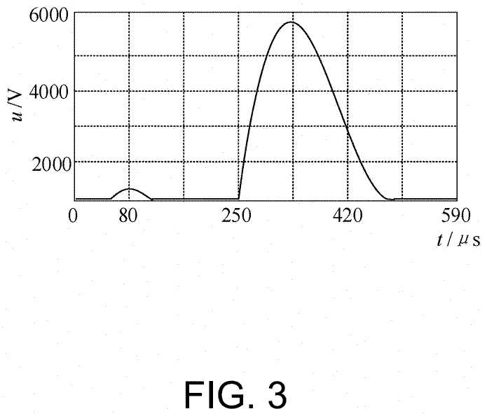

Topology of the analog circuit is a core of health state diagnosis and prediction, and Simulink simulation topology is shown in FIG. 2. Herein, direct current (DC) power supply of a pre-ionization circuit is powered by a capacitor, and the voltage is 12 kV. A voltage supply capacitor voltage of a main ionization circuit is 23 kV. In an embodiment of the disclosure, first, a power supply capacitor of a circuit is charged to a given voltage, and a switch S1 is turned off for 120 μs to complete a pre-ionization process. Next, after waiting for 130 μs, a switch S2 is turned off to complete a main ionization process, and a xenon lamp on the end discharge circuit is finally lit. A schematic graph of a discharge voltage waveform is shown in FIG. 3. From FIG. 3, it can be seen that the pre-ionization process and the main ionization process are considerably different from each other in time and energy amplitude, and the two discharge processes should be analyzed independently.

RT-LAB may directly apply a dynamic system mathematical model established by MATLAB/Simulink to real-time simulation, control, testing, and other related fields. A complete solution for rapid prototyping and hardware in-loop testing may build a dynamic model in a short period of time through engineering simulation or a real-time system in a loop. In this way, a simple design process of an engineering system is provided. In order to accurately simulate a degradation process of a core energy assembly circuit, all experimental processes in the embodiments of the disclosure are completed based on a platform.

The embodiment of the disclosure mainly relates to energy storage components in the circuit: a capacitor, an inductance, and an energy component: analysis of a degradation state of a xenon lamp assembly, and a component parameter deviation rated value of 60% is considered to be a complete failure state. According to degradation characteristics of these components, parameters thereof change continuously and slowly in the degradation process. In the embodiments of the disclosure, a degradation cycle number selected in a simulation process is 100 to 200, and 4 is a step value. A maintenance cycle number of a circuit health state is the degradation cycle number, so that circuit degradation under an actual condition may be fully simulated. Detailed circuit parameters are shown in Table 1.

TABLE 1
Circuit Degradation Parameter Table

| Degradation | Component | Degradation | Nominal | Failure | Parameter Absolute |
|---|---|---|---|---|---|
| Type | Parameter | Cycle | Value | Value | Change Value |
| 1 | K₁₋ₖ↓ | 100 to 200 | 94.48 | 37.792 | 0.283 to 0.567 |
| 2 | L₁₋ₖ↓ | 100 to 200 | 140 μH | 56 μH | 0.42 μH to 0.82 μH |
| 3 | L₂₋₁↓ | 100 to 200 | 100 μH | 40 μH | 0.3 μH to 0.6 μH |
| 4 | L₃₋ₖ↓ | 100 to 200 | 30 μH | 12 μF | 90 pH to 180 pH |
| 5 | C₁₋ₖ↓ | 100 to 200 | 87 μH | 34.8 μF | 261 pF to 522 pF |
| 6 | C₂₋₁↓ | 100 to 200 | 14 μH | 5.6 μF | 42 pF to 84 pF |

Herein, k=1, 2, 3, . . . , 10, referring to a component serial number. Parameter values of parallel components in a test circuit in the embodiments of the disclosure are the same at the same time. ↓ refers to that that the parameter value is reduced compared to the nominal value, and a total of 156 degraded data samples are provided. The current and voltage of the xenon lamp assembly satisfy the following relation formulas:

I=K\sqrt{U} (1)

where K represents a proportional coefficient of the xenon lamp device, U represents a voltage on both sides of the xenon lamp device, and I represents a current on both sides of the xenon lamp device.

In order to simulate an influence of external noise on normal operation of the circuit, in this embodiment, Gaussian white noise with a signal-to-noise ratio SNR unit of 40 dB is added in the circuit degradation simulation process. The added noise c satisfies the following relation formulas:

ε□N(0,σ²) (2)

where σ² is determined by SNR and the following formula:

$$SNR = \frac{1}{\sqrt{π}} {\int }_{\sqrt{\frac{{\sum }_{i = 1}^{N} {x}_{i}}{2 {σ}^{2}}}}^{∞} {e}^{- {v}^{2}} dv \qquad ( 3 )$$

(2) A time domain feature of each of the output signals of each sensor is extracted by using a time-series transformation method, and a health index of each of the devices is built according to the time domain feature.

In the embodiments of the disclosure, the health index of each of the devices is built through

$$dis ( {x}_{1} , {x}_{2} ) = 1 - {cos}^{- 1} ( \frac{{x}_{1} \cdot {x}_{2}}{\vert {x}_{1} \vert \vert {x}_{2} \vert} ) \cdot \frac{1}{π} , where {x}_{1} = ( {x}_{1}^{( 1 )} , {x}_{1}^{( 2 )} , … , {x}_{1}^{( n )} )$$

refers to the time domain feature of the output signal of the device under a healthy state, x₂=(x₂⁽¹⁾, x₂⁽²⁾, . . . , x₂⁽ⁿ⁾) refers to the time domain feature of the output signal of the device in an aging process, and n represents a length of a time domain feature vector.

Further, in step (2), ten time domain features of the extracted output signals are:

| Serial Number | Feature |
|---|---|
| 1 | tf₁ = max(sₜ) |
| 2 | ${tf}_{2} = \frac{1}{N} {\sum }_{t = 1}^{N} {s}_{t}$ |
| 3 | ${tf}_{3} = \frac{1}{N} {\sum }_{t = 1}^{N} {s}_{t}^{2}$ |
| 4 | ${tf}_{4} = \sqrt{\frac{1}{N} {\sum }_{t = 1}^{N} {( {s}_{t} - \overline{s} )}^{2}}$ |
| 5 | ${tf}_{5} = \sqrt{\frac{1}{N} {\sum }_{t = 1}^{N} {( {s}_{t} - \overline{s} )}^{3}}$ |
| 6 | ${tf}_{6} = \frac{{tf}_{5}^{2}}{{tf}_{4}^{3}}$ |
| 7 | ${tf}_{7} = \frac{{tf}_{1}}{\vert \overline{s} \vert}$ |
| 8 | ${tf}_{8} = \frac{{tf}_{1}}{{tf}_{3}}$ |
| 9 | ${tf}_{9} = \frac{{tf}_{1}}{{tf}_{2}}$ |
| 10 | ${tf}_{10} = \frac{\frac{1}{N} {\sum }_{t = 1}^{N} {( {s}_{t} - \overline{s} )}^{4}}{{tf}_{4}^{4}}$ |

Herein, sₜ is an output signal value at a t point (i.e., time t) in a current secondary degradation process, N is a total number of output signal points of a secondary degradation sample, and s̅ represents an arithmetic average value of the output signals of the secondary degradation sample.

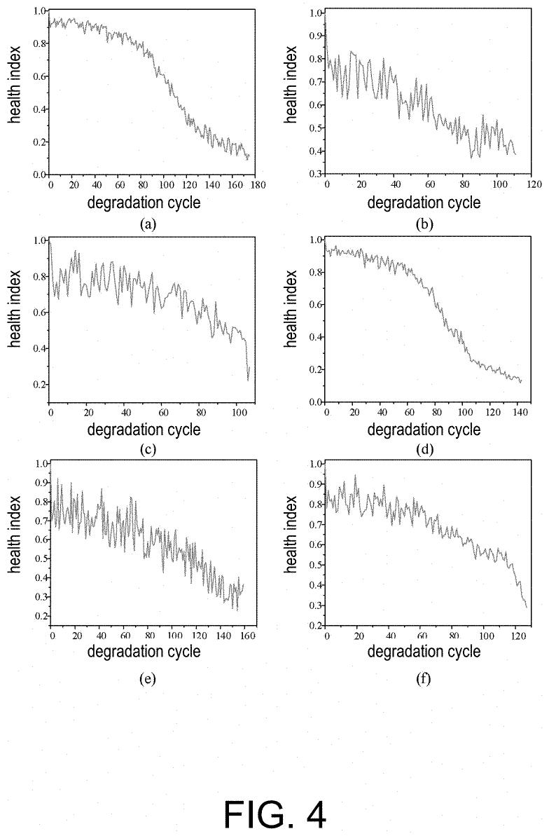

According to the analysis of step (2), the pre-ionization process and the main ionization process are independently analyzed, it thus can be seen that a single sample vector has 60 time domain features. Because amplitude of each time series component is different, in order to simplify calculation and effectively use independent information contained in each component, the sample vector is required to be normalize:

$$\overline{{x}_{i}} = 2 \frac{{x}_{i} - min {x}_{i}}{max {x}_{i} - min {x}_{i}} - 1 \qquad ( 4 )$$

where xᵢ is an i^{th} time series feature sample, and x̅ᵢ is a normalized time series sample. It thus can be seen that a normalized sample range is within [−1,1]. An angular similarity algorithm is used to calculate similarity between the sample vector and the an undegraded sample vector in the degradation process, and such value is the health index. Schematic graphs of the health index curves are shown in FIG. 4. Among them, each component selects only one degradation process. (a) is the L₂₋₁ health index curve, (b) is the health index curve, (c) is the C₂₋₁ health index curve, (d) is the health index curve, (e) is the L₃₋₁ health index curve, and (f) is the K₁₋₁ health index curve. From FIG. 4, it can be seen that the curves show a uniform downward trend along with linear degradation of the components and devices, which may reasonably reflect the degree of circuit degradation.

(3) Whether the analog circuit to be diagnosed is degraded is identified based on the health index of each of the devices combined with a time moving window and a convolutional neural network (CNN).

In the embodiments of the disclosure, the CNN includes three types of hidden layers including a convolutional layer, a pooling layer, and a Softmax layer. The time moving window is realized by truncating a certain number of signal features in a given length of a degradation period. To be specific, the time moving window establishes a signal matrix, and each of the signal features is divided into each row of the signal matrix, and a column number of the signal matrix corresponds to a degradation cycle number of a column signal. Since a single time moving window is a two-dimensional matrix, a single time moving window may be treated as a two-dimensional image.

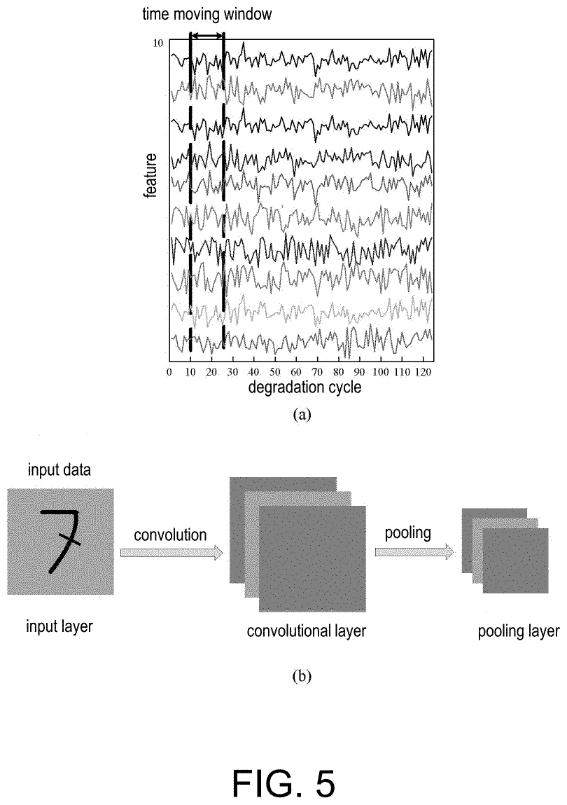

By using the time moving window to reconstruct a data format, the CNN may process multiple one-dimensional data at the same time. In the embodiments of the disclosure, an input sample of the CNN is one time moving window. In FIG. 5, (a) represents one time moving window, and (b) represents calculation steps of the CNN. One dimension of the time moving window is the degradation cycle of the sample vector, and another dimension is an actual value of the sample vector. A common CNN includes the convolutional layer and the pooling layer, and a convolution operation c is provided as follows:

$${c}_{( a , b )} = {\sum }_{m} {\sum }_{n} {P}_{( a + m , b + n )} {K}_{( m , n )} = {( P * K )}_{( a , b )} \qquad ( 5 )$$

where P refers to an input amount of the time moving window, K refers to a two-dimensional convolution kernel, (a,b) refers to coordinates of a single point of a two-dimensional image P, and m and n respectively represent the step values in two directions of a and b in the convolution process.

The convolutional neural network includes three types of hidden layers including the convolutional layer, the pooling layer, and the Softmax layer. The convolutional layer is mainly used to simplify a signal feature, project a low-dimensional vector into a high-dimensional space, and obtain a compressed feature vector. The pooling layer operation further removes a redundant parameter and simplifies an input sample. The Softmax layer is mainly used for multi-label classification of an original output signal. In the embodiments of the disclosure, a training set and testing set are divided according to a ratio of 7:3. That is, 109 samples are randomly selected as the training set of the network, and 47 samples among the remaining samples are treated as the testing set. An input sample data length is 15, and CNN parameter setting is provided as shown in Table 2 below.

TABLE 2
CNN Parameter Setting

| Hidden Layer | Hidden Layer | Filter | |
|---|---|---|---|
| Type | Name | Number | Dimension |
| Convolutional | Convolutional | 30 | 1 × 24 |
| Layer | Layer 1 | | |
| | Convolutional | 15 | 1 × 6 |
| | Layer 2 | | |
| Pooling Layer | Maximum | — | 1 × 12 |
| | Pooling | | |
| | Layer 1 | | |
| | Maximum | — | 1 × 15 |
| | Pooling | | |
| | Layer 2 | | |

First, inputted data of the time moving window is identified by the network. In the training set, if a circuit is degraded at a starting point of the time sliding window, the time moving window is classified as 3. If only part of lengths of the time moving window are degraded, the time moving window is classified as 2. If all the lengths in the time moving window are normal signals, the time moving window is classified as 1.

Identification accuracy of the proposed CNN degradation identification method and identification accuracy of a support vector machine (SVM) are compared, and results are provided as shown in Table 3 below.

TABLE 3
Degradation Identification Accuracy Comparison Results

| Prediction Method | Training Set (%) | Testing Set |
|---|---|---|
| CNN | 98.49 | 98.36 |
| SVM | 99.97 | 78.52 |

From Table 3, it can be seen that the identification accuracy of the training set of the CNN provided by the disclosure is equivalent to that of the SVM. Nevertheless, the recognition accuracy of the testing set is significantly greater than that of the SVM method, meaning that the method may be used to accurately identify the degradation starting point.

(4) Part of hidden layers of the CNN together with a long short term memory-recurrent neural network (LSTM-RNN) are multiplexed to estimate a state of a degraded circuit.

If the time moving window is classified as 3 by the CNN, it is considered that the analog circuit is degraded starting from this time moving window. Therefore, the time moving window is transmitted to the LSTM-RNN through feature information extracted by the hidden layers in the CNN for health state estimation. A LSTM network does not have the problem of gradient disappearance or gradient explosion compared to a conventional RNN network and mainly includes three types of gates: an input gate, an output gate, and a forget gate.

An input gate iᵢ affects information passed to the next step and a change of an internal state of a LSTM unit. The output gate oᵢ reviews and changes part of an output amount of the internal state of the LSTM. The forget gate fᵢ infers and merges censored and filtered information.

A mathematical calculation process is provided as follows:

iᵢ=σ·(wᵢₓxᵢ+wᵢₕhᵢ₋₁+bᵢ) (6)

oᵢ=σ·(wₒₓxᵢ+wₒₕhᵢ₋₁+bₒ) (7)

fᵢ=σ·(w_{fx}xᵢ+w_{fh}hᵢ₋₁+b_{f}) (8)

where wᵢₓ, wₒₓ, and w_{fx} are weight coefficients of an input amount xᵢ corresponding to different gates, wᵢₕ, wₒₕ and w_{fh} are weight coefficients of a process variable hᵢ₋₁ corresponding to the input gate, the output gate, and the forget gate, bᵢ, bₒ, and b_{f} are biasing coefficients corresponding to different gates, and σ is a sigmoid function:

$$σ ( z ) = \frac{1}{1 + {e}^{- z}} \qquad ( 9 )$$

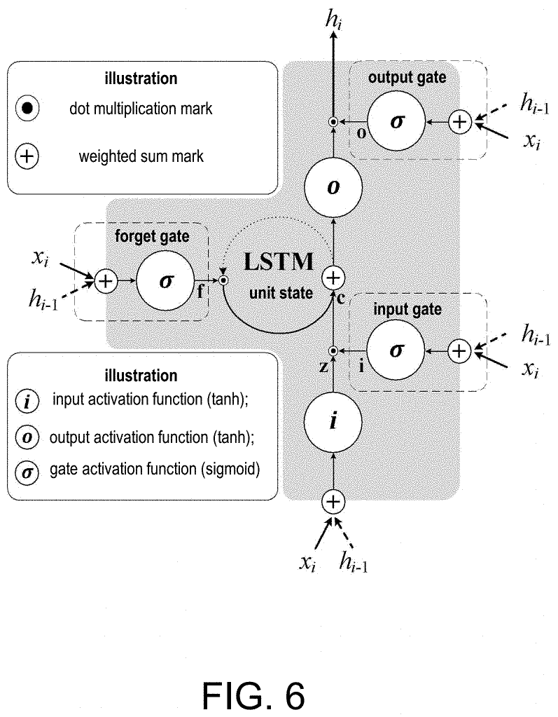

A single LSTM unit is shown in FIG. 6, and a calculation method of the related parameters in FIG. 6 is provided as follows:

zᵢ=φ(w_{zx}xᵢ+w_{zh}hᵢ₋₁+b_{z}) (10)

cᵢ=zᵢ□iᵢ+cᵢ₋₁□fᵢ (11)

hᵢ=φ(cᵢ)□oᵢ (12)

where w_{zx}, w_{zh}, and b_{z} are the weight coefficients and biasing amounts of the input amount xᵢ and the process variable hᵢ₋₁ at an input node, respectively. cᵢ and cᵢ₋₁ refer to the internal state and a previous state of the LSTM at that time, □ is a dot multiplication symbol, and φ is a tanh function:

$$φ ( z ) = \frac{{e}^{z} - {e}^{- z}}{{e}^{z} + {e}^{- z}} \qquad ( 11 )$$

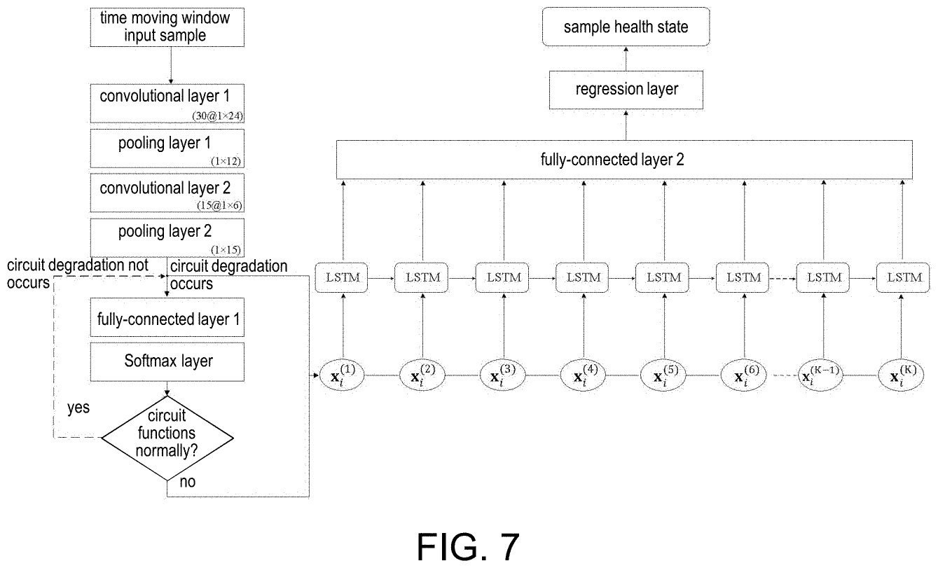

A diagram of a structure of the multiplexing CNN provided by the embodiments of the disclosure is shown in FIG. 7.

To be specific, an activation function of the hidden layers inside the multiplexing CNN is a ReLu function, and an optimization algorithm is an AdaGrad optimization algorithm, which minimizes a loss function by adaptively adjusting a learning rate.

In order to optimize the related internal parameters in the multiplexing CNN, the AdaGrad optimization algorithm is adopted in the embodiments of the disclosure to optimize global parameters, and an expression of an error function is:

$$L ( θ ) = \frac{1}{N} {\sum }_{i = 1}^{N} {‖ P ( {X}_{i} ; θ ) - {Y}_{i} ‖}^{2} \qquad ( 12 )$$

where N refers to a number of samples, Yᵢ is an actual measured value, and P(Xᵢ;θ) is a network predicted value.

The process of the AdaGrad algorithm updating the network parameters is as follows: gᵢ is an initial average gradient of an error function L(θ) to an initial hyperparameter set θ:

$${g}_{i} = \frac{1}{N} ∇ θ {\sum }_{i = 1}^{N} L ( i , θ ) \qquad ( 13 )$$

cumulative historical gradient vᵢ:

$${v}_{i} = {\sum }_{t = 0}^{i} {( {g}_{t} )}^{2} \qquad ( 14 )$$

Δθᵢ is the increment of the a hyperparameter set θ, an initial learning rate η is treated as 0.001, and an ε value is treated as 10⁻⁷:

$$\begin{matrix}{Δθ}_{i} = - η \frac{{g}_{i}}{\sqrt{{v}_{i}} + ɛ} & ( 18 ) \\ {θ}_{i + 1} = {θ}_{i} + {Δθ}_{i} & ( 19 )\end{matrix}$$

The AdaGrad optimization algorithm may adaptively adjust the learning rate, calculation may be easily performed, and only few process variables are required to be stored.

(5) With reference to related evaluation indicators, the effectiveness of the circuit health state estimation method is evaluated.

Two evaluation mechanisms are used in the embodiments of the disclosure, namely a scoring function and a root mean square error, to evaluate a prediction effect.

The scoring function is provided as follows:

$$\begin{matrix}g = {\sum }_{i = 1}^{N} {g}_{i} & ( 20 ) \\ {g}_{i} = \{ \begin{matrix}exp ( - \frac{{e}_{i}}{13} ) - 1 , {e}_{i} < 0 , \\ exp ( \frac{{e}_{i}}{10} ) - 1 , {e}_{i} \geq 0.\end{matrix} & ( 21 ) \\ {e}_{i} = \overline{{HI}_{i}} - {HI}_{i} & ( 22 )\end{matrix}$$

where H̅I̅ᵢ refers to a health index obtained by the i^{th} prediction, and HIᵢ refers to the i^{th} calculated health index.

The root mean square error is provided as follows:

$$RMSE = \sqrt{\frac{1}{N} {\sum }_{i = 1}^{N} {e}_{i}^{2}} \qquad ( 23 )$$

The prediction effect of the method of identifying and estimating the complex analog circuit failure provided by the disclosure is evaluated by using the above two evaluation criteria and is compared with the prediction effects of five mainstream data-driven algorithms: the deep CNN, LSTM, SVM, gated recurrent unit (GRU), and gradient boosting, and the results are shown in Table 4 as follows. Part of the health state prediction results are shown in Table 8, where (a) is testing sample #4, (b) is testing sample #36, (c) is testing sample #56, (d) is testing sample #66, (e) is testing sample #75, (f) is testing sample #92, (g) is testing sample #103, (h) is testing sample #112, and (i) is testing sample #116.

TABLE 4
Prediction Performance Comparison Results

| Prediction | Root Mean | Scoring |
|---|---|---|
| Method | Square Error | Function |
| Method of | 0.063 | 15.90 |
| Disclosure | | |
| DCNN | 0.103 | 26.43 |
| LSTM | 0.083 | 18.65 |
| SVM | 0.193 | 98.63 |
| GRU | 0.082 | 17.494 |
| Gradient | 0.078 | 30.132 |
| Boosting | | |

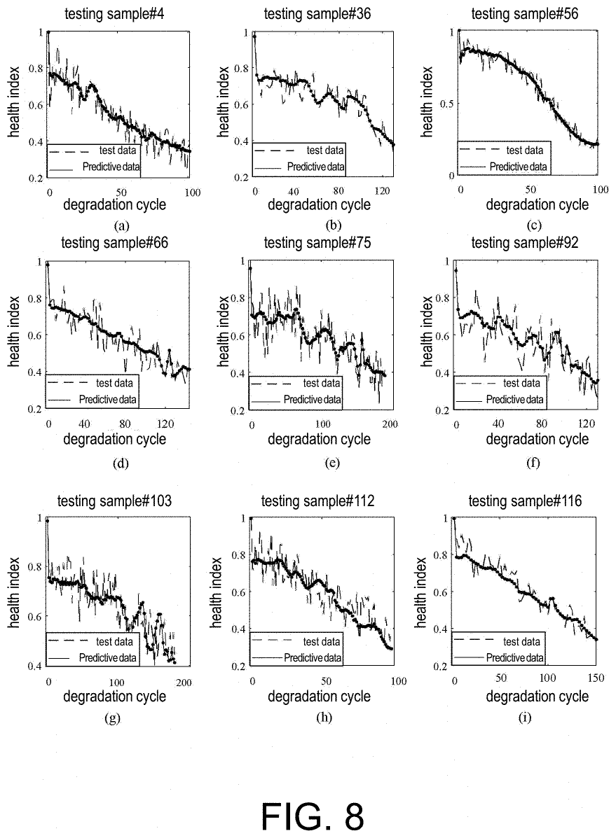

From Table 4 and FIG. 8, it can be seen that the multiplexing CNN provided by the disclosure provides the minimum root mean square error and the scoring function, and a difference between a predicted curve and the actual health state of the analog circuit is minor, such that high computing efficiency is achieved and accurate identification is provided.

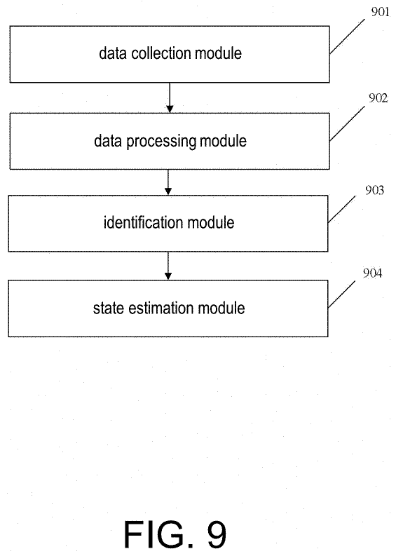

FIG. 9 is a schematic diagram of a structure of a system of identifying and estimating a complex analog circuit failure according to an embodiment of the disclosure, and the system includes a data collection module 901, a data processing module 902, an identification module 903, and a state estimation module 904. The data collection module 901 is configured to build a degradation simulation model of an analog circuit to be diagnosed, perform a parameter aging simulation experiment on different devices, and collect output signals of the devices under various parameter conditions. The data processing module 902 is configured to extract a time domain feature of each of the output signals by using a time-series transformation method and build a health index of each of the devices according to the time domain feature. The identification module is configured to identify whether the analog circuit to be diagnosed is degraded based on the health index of each of the devices combined with a time moving window and a CNN. The state estimation module, configured to multiplex part of hidden layers of the convolutional neural network together with a LSTM-RNN to estimate a state of a degraded circuit.

In the embodiments of the disclosure, the system further includes an evaluation module, adopting a related evaluation indicator to evaluate a prediction effect. The evaluation indicator includes: a scoring function and a root mean square error.

Herein, specific implementation of each of the modules may be found with reference to the description of the method embodiments, and description thereof is not provided in the embodiments of the disclosure.

The disclosure further provides a computer readable storage medium such as a flash memory, hard disk, multimedia card, card-type memory (e.g., SD or DX memory and the like), random access memory (RAM), static random access memory (SRAM), read only memory (ROM), electronic erasable programmable read-only memory (EEPROM), programmable read-only memory (PROM), magnetic memory, disk, CD, server, App store, etc., and the computer readable storage medium stores a computer program. The computer program performs the method of identifying and estimating the complex analog circuit failure in the method embodiments when being executed by a processor.

In general, the above technical solutions provided by the disclosure have the following beneficial effects compared with the related art. In the disclosure, the early failure starting point of the analog circuit is identified and diagnosed based on historical data through the multiplexing deep neural network, and the health state of the circuit is predicted based on the starting point. The degradation simulation model of the analog circuit to be diagnosed is built, and the parameter aging simulation experiment is performed on different devices. The time domain feature of each of the output signals is extracted by using the time-series transformation method, and a health index of each of the devices is built based on angle similarity. Whether the analog circuit to be diagnosed is degraded and a starting point of degradation are identified by combining the time moving window and the convolutional neural network. Part of hidden layers of the convolutional neural network and the long short term memory-recurrent neural network are multiplexed to estimate the health state of the degraded analog circuit. With reference to related evaluation indicators, the prediction accuracy of the disclosed method is evaluated. In the disclosure, the starting point of the failure state of the analog circuit may be accurately identified, and at the same time, the health state of the analog circuit is effectively estimated, such that high computing efficiency is achieved and accurate identification is provided.

Note that according to implementation requirements, each step/part described in the disclosure may be further divided into more steps/parts, or two or more steps/parts or partial operations of a step/part may be combined into a new step/part to accomplish the goal of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of identifying and estimating a complex analog circuit failure, comprising:
(1) building a degradation simulation model of an analog circuit to be diagnosed, performing a parameter aging simulation experiment on different devices, collecting output signals of the devices under various parameter conditions;
(2) extracting a time domain feature of each of the output signals by using a time-series transformation method, building a health index of each of the devices according to the time domain feature;
(3) identifying whether the analog circuit to be diagnosed is degraded based on the health index of each of the devices combined with a time moving window and a convolutional neural network (CNN); and
(4) multiplexing part of hidden layers of the convolutional neural network together with a long short term memory-recurrent neural network (LSTM-RNN) to estimate a state of a degraded circuit.

2. The method according to claim 1, wherein the health index of each of the devices is built through
$$dis ( {x}_{1} , {x}_{2} ) = 1 - {cos}^{- 1} ( \frac{{x}_{1} \cdot {x}_{2}}{\vert {x}_{1} \vert \vert {x}_{2} \vert} ) \cdot \frac{1}{π} ,$$
wherein x₁=(x₁⁽¹⁾, x₁⁽²⁾, . . . , x₁⁽ⁿ⁾) refers to the time domain feature of the output signal of the device under a healthy state, x₂=(x₂⁽¹⁾, x₂⁽²⁾, . . . , x₂⁽ⁿ⁾) refers to the time domain feature of the output signal of the device in an aging process, and n represents a length of a time domain feature vector.

3. The method according to claim 2, wherein in step (2), ten time domain features of the extracted output signals are: tf₁=max(sₜ),
$${tf}_{2} = \frac{1}{N} {\sum }_{t = 1}^{N} {s}_{t} , \\ {tf}_{3} = \frac{1}{N} {\sum }_{t = 1}^{N} {s}_{t}^{2} , \\ {tf}_{4} = \sqrt{\frac{1}{N} {\sum }_{t = 1}^{N} {( {s}_{t} - \overline{s} )}^{2}} , \\ {tf}_{5} = \sqrt{\frac{1}{N} {\sum }_{t = 1}^{N} {( {s}_{t} - \overline{s} )}^{3}} , \\ {tf}_{6} = \frac{{tf}_{5}^{2}}{{tf}_{4}^{3}} , \\ {tf}_{7} = \frac{{tf}_{1}}{\vert \overline{s} \vert} , \\ {tf}_{8} = \frac{{tf}_{1}}{{tf}_{3}} , \\ {tf}_{9} = \frac{{tf}_{1}}{{tf}_{2}} , and$$
$${tf}_{10} = \frac{\frac{1}{N} {\sum }_{t = 1}^{N} {( {s}_{t} - \overline{s} )}^{4}}{{tf}_{4}^{4}} ,$$
wherein sₜ is an output signal value at a t point in a current secondary degradation process, N is a total number of output signal points of a secondary degradation sample, and s̅ represents an arithmetic average value of the output signals of the secondary degradation sample.

4. The method according to claim 1, wherein the convolutional neural network comprises three types of hidden layers comprising a convolutional layer, a pooling layer, and a Softmax layer, and the time moving window is realized by truncating a certain number of signal features in a given length of a degradation period, such that the time moving window establishes a signal matrix, wherein each of the signal features is divided into each row of the signal matrix, and a column number of the signal matrix corresponds to a degradation cycle number of a column signal.

5. The method according to claim 2, wherein the convolutional neural network comprises three types of hidden layers comprising a convolutional layer, a pooling layer, and a Softmax layer, and the time moving window is realized by truncating a certain number of signal features in a given length of a degradation period, such that the time moving window establishes a signal matrix, wherein each of the signal features is divided into each row of the signal matrix, and a column number of the signal matrix corresponds to a degradation cycle number of a column signal.

6. The method according to claim 3, wherein the convolutional neural network comprises three types of hidden layers comprising a convolutional layer, a pooling layer, and a Softmax layer, and the time moving window is realized by truncating a certain number of signal features in a given length of a degradation period, such that the time moving window establishes a signal matrix, wherein each of the signal features is divided into each row of the signal matrix, and a column number of the signal matrix corresponds to a degradation cycle number of a column signal.

7. The method according to claim 4, wherein step (3) further comprises:
identifying the signal matrix truncated by the time moving window through the convolutional neural network to identify whether the analog circuit to be diagnosed is degraded and further determining the degradation cycle number at which the degradation starts if the analog circuit to be diagnosed is degraded.

8. The method according to claim 7, wherein step (4) further comprises:
sending hidden feature information of an input signal of the degraded circuit extracted by the convolutional neural network in the long short term memory-recurrent neural network for health state estimation and adopting an AdaGrad algorithm to update a network parameter.

9. The method according to claim 8, wherein the method further comprises:
adopting a related evaluation indicator to evaluate a prediction effect, wherein the evaluation indicator comprises: a scoring function and a root mean square error.

10. A system of identifying and estimating a complex analog circuit failure, comprising:
a data collection module, configured to build a degradation simulation model of an analog circuit to be diagnosed, perform a parameter aging simulation experiment on different devices, collect output signals of the devices under various parameter conditions;
a data processing module, configured to extract a time domain feature of each of the output signals by using a time-series transformation method, build a health index of each of the devices according to the time domain feature;
an identification module, configured to identify whether the analog circuit to be diagnosed is degraded based on the health index of each of the devices combined with a time moving window and a convolutional neural network (CNN); and
a state estimation module, configured to multiplex part of hidden layers of the convolutional neural network together with a long short term memory-recurrent neural network (LSTM-RNN) to estimate a state of a degraded circuit.

11. The system according to claim 10, wherein the system further comprises:
an evaluation module, adopting a related evaluation indicator to evaluate a prediction effect, wherein the evaluation indicator comprises: a scoring function and a root mean square error.

12. A computer readable storage medium, storing a computer program, wherein the computer program performs the steps provided in claim 1 when being executed by a processor.
